(19) United States
(12) Patent Application Publication
(10) Pub. No.: US 2009/0174286 A1
(43) Pub. Date: Jul. 9, 2009

(54) METHODS FOR ADJUSTING FREQUENCY OF PIEZOELECTRIC VIBRATING PIECES, PIEZOELECTRIC DEVICES, AND TUNING-FORK TYPE PIEZOELECTRIC OSCILLATORS

(75) Inventors: Masahiro Yoshimatsu, Saitama (JP); Kozo Ono, Saitama (JP); Hiroshi Uehara, Saitama (JP); Toshiaki Takeuchi, Saitama (JP)

Correspondence Address: KLARQUIST SPARKMAN, LLP, 121 SW SALMON STREET, SUITE 1600, PORTLAND, OR, 97204, US

(73) Assignee: Nihon Dempa Kogyo Co., Ltd.,

(21) Appl. No.: 12/350,158

(22) Filed: Jan. 7, 2009

(30) Foreign Application Priority Data
Jan. 9, 2008 (JP) JP 2008-002174

(51) Int. Cl. H01L 41/04

(52) U.S. Cl. 310/321

(57) ABSTRACT

A piezoelectric frame includes a tuning-fork type piezoelectric vibrating piece having excitation electrodes on each of at least two vibrating arms extending in a first direction from one end of a base portion thereof. Respective supporting arms extend in a first direction from respective external edges of the vibrating arms. An outer frame portion surrounds the tuning-fork type piezoelectric vibrating piece. The connecting portions have designated widths and connect the respective supporting arms to the outer frame portion. During manufacture, the designated widths are trimmed (e.g., by a pulsed laser) until the desired vibration frequency is obtained.

### CROSS-REFERENCE TO RELATED APPLICATION

This application claims priority to, and the benefit of, Japan Patent Application No. 2008-002174, filed on Jan. 9, 2008, in the Japan Patent Office, the disclosure of which is incorporated herein by reference in its entirety.

### FIELD

This invention is related to, inter alia, methods for manufacturing tuning-fork type piezoelectric vibrating elements having supporting arms which controls frequency adjustment by using a piezoelectric substrate made of crystal,

### DESCRIPTION OF THE RELATED ART

With the progress of miniaturization and/or increases in the operating frequency of mobile communication apparatus and office automation (OA) equipment, piezoelectric oscillators used in this equipment must be progressively smaller and/or operate at higher frequency. Also required are piezoelectric oscillators that can be surface mounted (SMD: Surface Mount Device) on circuit boards. The manufacturing process of miniaturized piezoelectric vibrating elements need a step of adjusting variability of oscillation frequency of each piece occurred in the manufacturing process to acquire desired frequency.

Previously, frequency adjustment has been conducted by evaporation of portions of metal films formed on the tips of the vibrating arms of a tuning-fork type piezoelectric vibrating element (herein after “tuning-fork type piezoelectric vibrating piece”). In Japan Unexamined Patent Application No. 2003-060470, frequency adjustments are made of a tuning-fork type piezoelectric vibrating piece as shown in FIGS. 8A and 8B. FIG. 8A is an enlarged top view of the tips of vibrating arms 210 of the tuning-fork type piezoelectric vibrating piece, and FIG. 8B is a side view of the configuration of FIG. 8A. Each vibrating arm 210 includes a first metal layer 201 and a second metal layer 202. The first metal layer 201 is formed on the second metal layer. These metal layers 201, 202 provide mass to the tips of the vibrating arms 210. The mass of the arms determines their vibration frequency. Adjustment of oscillation frequency is begun with a tuning-fork type piezoelectric vibrating piece having sufficient amounts of the metal layers 201, 202 to provide the arms 210 with a lower vibration frequency than designated. To reduce arm mass and increase vibration frequency, selected regions of the first metal film 201 are removed (by evaporation) in a rough frequency adjustment. Then, selected regions of the second metal film 202 are removed (by evaporation) in a fine frequency adjustment. These selective removals of portions of the metal films 201, 202 increase the vibration frequency of the tuning-fork type piezoelectric vibrating piece to the desired value.

To adjust the oscillation frequency of a tuning-fork type piezoelectric vibrating piece that vibrates at a higher frequency than designated, selected regions of a metal film 203 are evaporated under conditions in which the evaporated material becomes deposited near the tips of the arms 210. Thus, by adding mass to the vibrating arms 210, their vibration frequency is reduced.

However, whenever a metal film is evaporated for the purpose of mass addition to the vibrating arms, the evaporated material also spreads to other locations where the material may become redeposited. For example, the evaporated material may travel to and deposit on excitation electrodes of the tuning-fork type piezoelectric vibrating piece. The evaporated material may also cause the CI value of the tuning-fork type piezoelectric vibrating piece to change after completion of the oscillation frequency adjustment or may generate spurious undesired vibration frequencies. Increasing the CI and/or generating spurious vibrations deteriorates the quality characteristic of the tuning-fork type piezoelectric vibrating piece and degrades the yield of the manufacturing process. In addition, in conventional manufacturing methods, extra steps are required for forming the metal films used for rough and fine adjustments and for performing the frequency adjustments.

The present invention includes, inter alia, fabricating a piezoelectric frame comprising a tuning-fork type piezoelectric vibrating piece on which frequency adjustments can be performed without processing the vibrating arms that dominate the performance characteristics of the tuning-fork type piezoelectric vibrating piece.

### SUMMARY

This disclosure sets forth several aspects of the invention. A first aspect pertains to a piezoelectric frame comprised of a tuning-fork type piezoelectric vibrating piece comprising a base portion, at least a pair of vibrating arms extending in a first direction from one edge of the base portion, and respective excitation electrodes on the vibrating arms. A respective supporting arm extends in the first direction from an external edge of each vibrating arm. An outer frame portion surrounds the tuning-fork type piezoelectric vibrating piece. Respective connecting portions having designated widths connect the supporting arms to the outer frame portion. According to this configuration, the connecting portions having designated widths, connecting the supporting arms to the frame, can be altered to adjust the vibration frequency of the tuning-fork type piezoelectric vibrating piece. By performing frequency adjustment in this way, unintended rises in the CI value of the tuning-fork type piezoelectric vibrating piece and/or generation of spurious frequency components are avoided.

The connecting portions are altered by making small controlled cuts thereof that result in removal of very small amounts of material from the connecting portions. For example, portions of the designated widths are slightly narrowed by cutting away material, to cause the tuning-fork type piezoelectric vibrating piece to oscillate with a designated frequency. In other words, the piezoelectric vibrating pieces are manufactured having a slightly lower frequency than ultimately desired. During manufacture of devices comprising the piezoelectric vibrating pieces, controlled cuts are made (e.g., using a pulsed laser) in the connecting portions to remove small amounts of material therefrom, which produces corresponding slight increases in vibration frequency. In other words, according to this configuration, the oscillation frequency of the tuning-fork type piezoelectric vibrating piece is adjusted to a desired specific frequency by shaping the connecting portion, after manufacture of the connecting portion, more narrowly than the originally formed designated width.

The piezoelectric frame can be formed on the outer frame portion, with connecting electrodes that connect electrically to the excitation electrodes. By forming the connecting electrodes on the frame, they can be connected electrically to the excitation electrodes without adversely affecting the oscillation of the tuning-fork type piezoelectric vibrating piece.

According to another aspect, piezoelectric devices are provided that include a piezoelectric frame as summarized above, a lid covering the piezoelectric frame, and a base supporting the piezoelectric frame. Such a piezoelectric device does not exhibit unintended increases in CI value or spurious vibration frequencies.

In some embodiments the lid and base are made of glass that includes metal ions. A metal film is formed around the outer frame portion of the piezoelectric frame. Then, the metal film, the lid, and the base are bonded together by anodic bonding. By making the base and lid of glass, mass manufacture of piezoelectric devices is readily achieved.

In other embodiments the lid and base are made of a piezoelectric material, wherein the piezoelectric frame, the lid, and the base are bonded together by siloxane bonding. Making the base and lid of piezoelectric material is also amenable to mass production.

According to another aspect, methods are provided for adjusting the vibration frequency of a piezoelectric device. An embodiment of such a method comprises forming a piezoelectric frame having a tuning-fork type piezoelectric vibrating piece. The tuning-fork type piezoelectric vibrating piece comprises at least two vibrating arms extending in a first direction from one edge of a base portion thereof. The vibrating arms have respective excitation electrodes. A respective supporting arm is provided for each vibrating arm. The supporting arms extend in the first direction from respective outer edges of the vibrating arms. An outer frame portion surrounds the tuning-fork type piezoelectric vibrating piece. A respective connecting portion, having a designated width, connects each supporting arm to the outer frame portion. The method includes measuring oscillation frequency of the vibrating arms by connecting a potential to the excitation electrodes. Material is trimmed as required from the designated width of the connecting portions, based on the measured oscillation frequency, so as to remove mass from the connecting portions and correspondingly increase the vibration frequency. According to this embodiment, by altering the width of the connecting portion while measuring the oscillation frequency after forming the piezoelectric frame, the metal film does not spread around the device. As a result, the method produces piezoelectric devices that do not exhibit increases in CI value and do not generate unnecessary spurious vibrations.

The connecting electrodes can be formed on the outer frame portion where they can be electrically connected to the excitation electrodes. With such a configuration, the measuring step can be conducted by contacting respective probes to the connecting electrodes to measure the oscillation frequency. The probes desirably are not connected on the excitation electrodes but rather on the connecting electrodes. This allows frequency measurement and adjustments to be made with a piezoelectric device exhibiting an oscillation state similar to that of a complete device.

The frequency adjustment methods can include bonding steps. In a first bonding step, a base supporting the piezoelectric frame and the piezoelectric frame are bonded together. The measuring and trimming steps are conducted after the first bonding step. In this embodiment frequency adjustments can be conducted with a piezoelectric device exhibiting an oscillation state that is substantially that of a complete device.

In a second bonding step a lid, covering the piezoelectric frame, is bonded to the frame in a vacuum or inert-gas environment after the trimming step. Bonding the lid in this manner produces piezoelectric devices that can withstand long-term use.

In general, the tuning-fork type piezoelectric vibrating pieces have supporting arms and connecting portions. The connecting portions allow frequency changes to be made at regions where the supporting arms are connected to the outer frame portion. The frequency adjustments are performed while maintaining other performance characteristics of the tuning-fork type piezoelectric vibrating piece.

### BRIEF DESCRIPTION OF THE DRAWINGS

FIG. 1 is an isometric exploded view of an embodiment of a piezoelectric device 90.

FIG. 2A is a plan view of an embodiment of a crystal frame 20 including a first configuration of connecting portions.

FIG. 2B is a plan view of an embodiment of a crystal frame 20 including a second configuration of connecting portions.

FIG. 3A is a plan view of the underside (inside surface) of the first lid 11a of a first piezoelectric device 100.

FIG. 3B is a plan view of the crystal frame 20 having connecting portions, of the first piezoelectric device 100.

FIG. 3C is a plan view of the inside surface of a first base 3 la as used in the first piezoelectric device 100.

FIG. 3D is a vertical cross-sectional view of the first piezoelectric device 100.

FIG. 4A is a plan view of the under-surface (inside surface) of a second lid 11b as used in the second piezoelectric device 110.

FIG. 4B is a plan view of the crystal frame 20 having connecting portions, of the second piezoelectric device 110.

FIG. 4C is a plan view of the inside surface of the second base 31b as used in the second piezoelectric device 110.

FIG. 4D is a vertical cross-sectional view of the second piezoelectric device 110.

FIG. 5A is a perspective view of the irradiating position of a femtosecond laser FL as incident on the crystal frame 20.

FIG. 5B is an enlarged view of a connecting portion 26 being cut in a direction toward the base of the crystal frame.

FIG. 5C is an enlarged view of a connecting portion 26 being cut in a direction toward the tips of the vibrating arms.

FIG. 5D is an enlarged view of a connecting portion 26 being cut both toward the base of the crystal frame and toward the tips of the vibrating arms 24.

FIG. 5E is an enlarged view of a portion of a connecting portion 26 that has been cut.

FIG. 6 is a graph showing the relationship of the width W of a frequency-adjustment cutting area of a connecting portion versus frequency f of the respective vibrating arm.

FIG. 7 is a flow-chart of steps in an embodiment of a method for adjusting vibration frequency.

FIGS. 8A-8B are plan and side views, respectively, of vibrating arms 210 of a conventional tuning-fork type piezoelectric vibrating piece.

### DETAILED DESCRIPTION

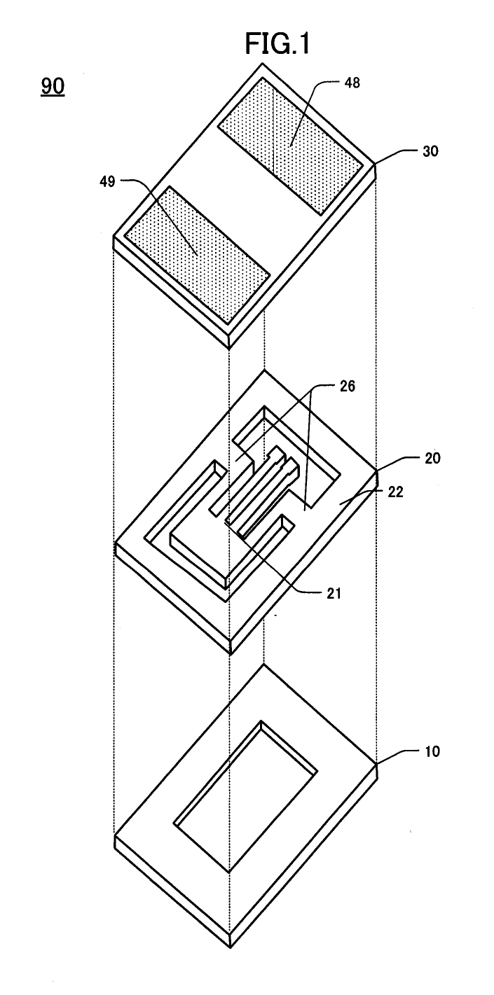

An embodiment of a piezoelectric device 90 of comprises, as shown in FIG. 1, a lid 10, a crystal frame 20, and a base 30, formed from respective substrates and formed as three-layer structure. FIG. 1 is a view from the base down to the lid. The depicted surface of the base 30 indicates that this device 90 is a surface-mounting device (SMD). The crystal frame 20 includes connecting portions 26 connecting the frame to the supporting arms of the tuning-fork type crystal vibrating piece in a manner allowing adjustment of vibration frequency. The lid 10 and base 30 can be formed of respective crystal substrates or of glass, while the frame 20 is made of a piezoelectric crystal material (e.g., quartz crystal).

In a first embodiment a piezoelectric frame comprises the tuning-fork type crystal vibrating piece, a peripheral frame, supporting arms, and connecting portions connecting the vibrating piece to the peripheral frame. Exemplary configurations of the frame (hereinafter termed “crystal frame 20 having connecting portions”) are described below.

In a second embodiment a crystal frame 20 having connecting portions, according to the first embodiment, is used as a crystal frame. A lid 10 and base 30 are formed of glass. A first piezoelectric device 100 is a piezoelectric device comprising the crystal frame 20 having connecting portions, to which are attached the base 30 and lid 10 made of glass.

A third embodiment comprises a crystal frame 20 having connecting portions, according to the first embodiment, a lid, and a base, all made of crystal substrates. The first piezoelectric device 100 is a piezoelectric device comprising the crystal frame 20 having connecting portions, to which are attached the base 30 and lid 10 made of crystal substrate.

A fourth embodiment is directed to a method for adjusting the vibration frequency of the crystal frame 20 having connecting portions.

### First Embodiment: Configuration of Crystal Frame 20 having Connecting Portions

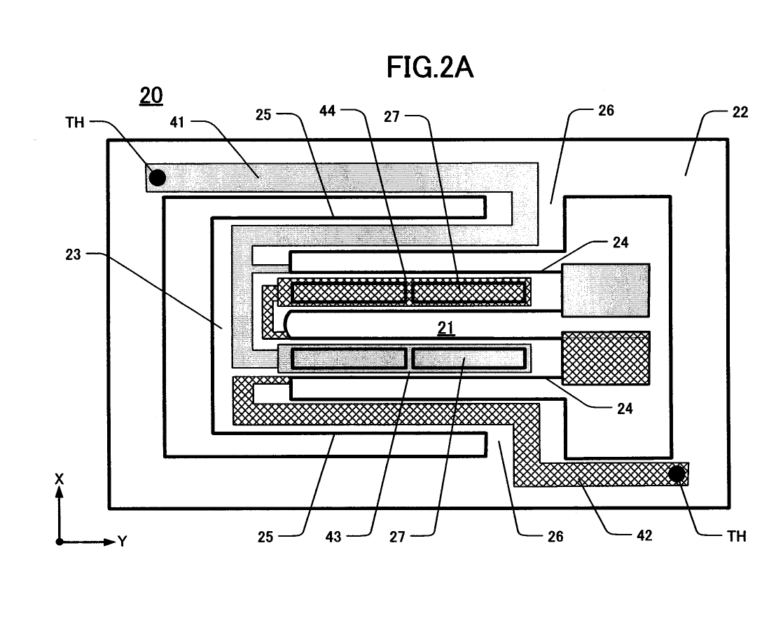

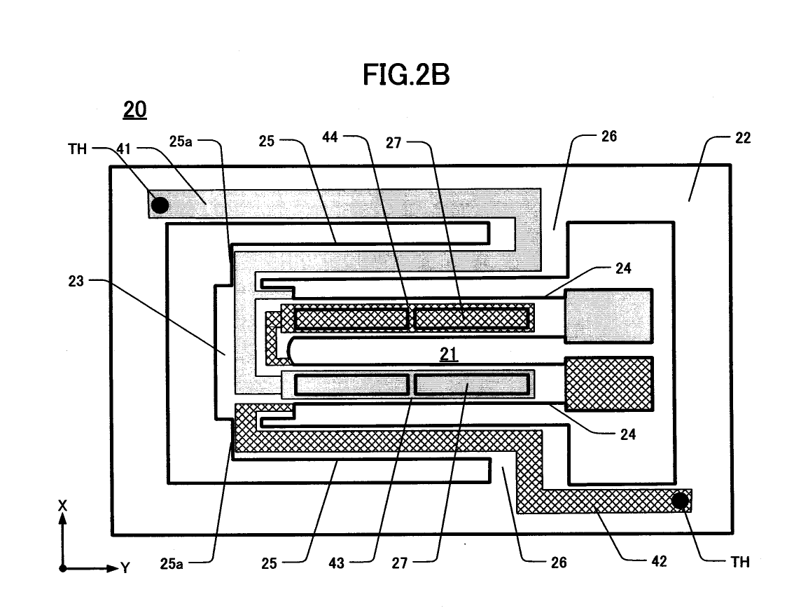

The crystal frame 20 having connecting portions, shown in FIG. 2A, comprises a tuning-fork type crystal vibrating piece 21 including a base 23 and vibrating arms 24, a crystal outer-frame portion 22, supporting arms 25, and connecting portions 26. The frame is formed from a single crystal substrate having uniform thickness. The tuning-fork type crystal vibrating piece 21 is a very small vibrating piece that oscillates at a frequency of, for example, 32.768 kHz.

The pair of vibrating arms 24 extends in the Y-direction from the base 23. Respective grooves 27 are formed on the upper and lower surfaces of the vibrating arms 24. For example, on the upper surface of one vibrating arm 24, two respective grooves 27 are formed; on the lower surface of the vibrating arm, two respective grooves 27 are also formed. I.e., four grooves are formed on each vibrating arm 24. A cross-section across a region of a vibrating arm where grooves 27 are present has a substantially H-shape. The grooves 27 reduce the CI of the tuning-fork type crystal vibrating piece 21. In this embodiment two grooves 27 are formed on each of the upper and lower surfaces of each vibrating arm 24; more generally, one or more grooves 27 are formed on each of the upper and lower surfaces. Even vibrating arms having no grooves 27 can be vibration-adjusted according to the invention.

The tips of the vibrating arms 24 are somewhat hammerhead-shaped, being wider than the arms themselves. The tips have constant width. On the hammerheads, metal films are formed for use as weights. The weights make the vibrating arms 24 oscillate easily whenever excitation voltage is being applied to the arms. The weights also ensure stable oscillation.

A first base electrode 41 and second base electrode 42 are formed on the upper surface of the crystal outer-frame portion 22, the base 23, the supporting arms 25, and the connecting portion 26. Separate first and second base electrodes 41, 42 are also formed on the lower surface of these structures. The first base electrodes 41 and second base electrodes 42 of the upper and lower surfaces are connected electrically using respective through-holes TH in the crystal frame.

The first base electrode 41 and the second base electrode 42 on the upper surface can be scratched using a probe needle during frequency adjustment because the needle directly contacts the electrodes; however, the electrodes on the lower surface cannot be directly contacted by a probe needle to ensure electrical conduction.

In addition, a first excitation electrode 43 and second excitation electrode 44 are formed on the upper, lower, and side surfaces of each of the vibrating arms 24. The first excitation electrode 43 is connected to the first base electrode 41, and the second excitation electrode 44 is connected to the second base electrode 42.

The supporting arms 25 extend parallel to the vibrating arms 24 (in the Y-direction) from one edge of the base 23. The supporting arms 25 reduce leakage of oscillation of the vibrating arms 24 to outside the piezoelectric device 90, and also lessen the vulnerability of the device to external temperature changes and physical impacts.

The crystal frame 22 is configured to connect the lid 10 and the base 30 together in a sandwich manner. The crystal frame 22 is also connected to the supporting arms 25 by the connecting portions 26. The connecting portions 26 are wider in the Y-direction than in the X-direction. The connecting portions 26 are originally formed wider and are cut to narrow them in a late stage of the manufacturing process. This cutting desirably is performed using a pulsed laser, for example a femtosecond laser. The narrower width has a designated vibration frequency. Thus, a piezoelectric 90 having the characteristics of a tuning-fork type piezoelectric vibrating piece that maintains its operational characteristics is manufactured.

The outline profile of and grooves 27 on the crystal frame 20 having connecting portions are formed by a conventional photoresist etching process. The electrodes are also formed by photoresist etching of the crystal frame 20 after the outline profile of the frame has been formed. After these steps, the crystal frame 20 having connecting portions, as shown in FIG. 2A, is completed.

FIG. 2B shows a quartz frame 20 having different connecting portions 26 than those of FIG. 2A. Specifically, in FIG. 2B, the left ends of the connecting portions 26 are different where they connect to the supporting arms 25, compared to FIG. 2A. Each supporting arm 25 in FIG. 2B has a narrow portion 25a extending from the base portion 23 in the X-direction (width direction); the remainder of the supporting arm 25 extends in the Y-direction parallel to the vibrating arms 24.

Since the supporting arms 25 extend the full distance between the base portion 23 and the connecting portion 26, the supporting arms 25 reduce the probability of leakage of oscillations of the vibrating arms 24 to outside the piezoelectric device 90. The supporting arms 25 also reduce the vulnerability of the device to external temperature changes and physical impacts.

### Second Embodiment: Configuration of the First Piezoelectric Device 100

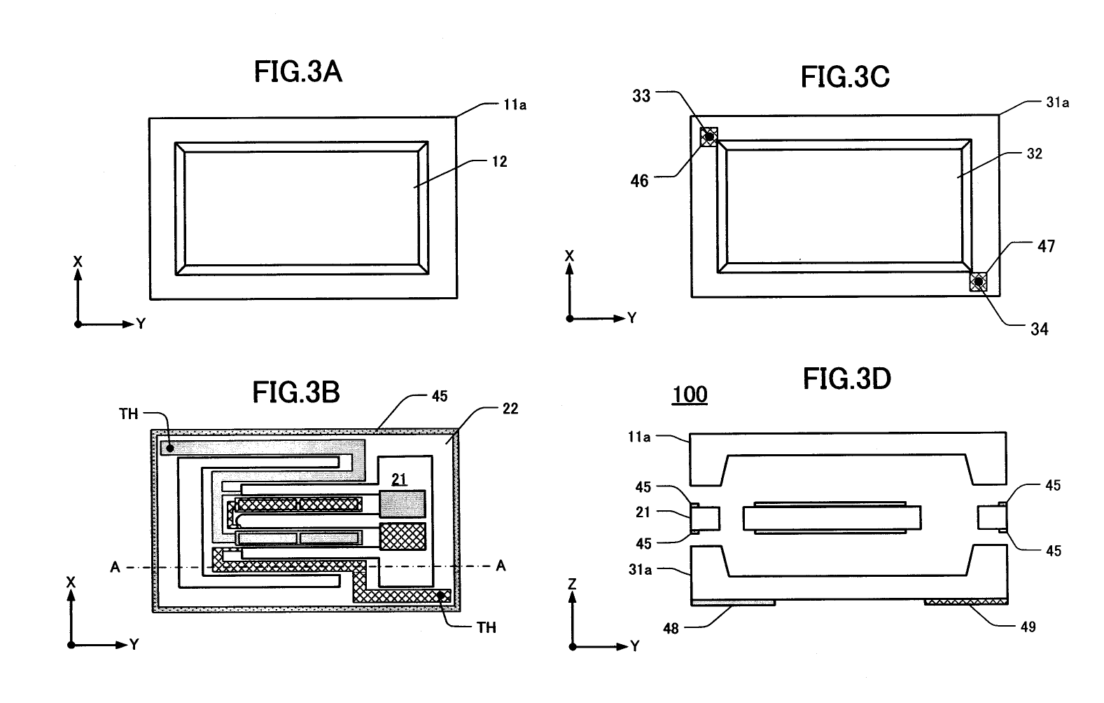

A first piezoelectric device 100, of which the lid 10 and base 30 are made of glass, is described with reference to FIGS. 3A-3D. FIGS. 3A-3D are schematic orthographic views of the first piezoelectric device 100 this embodiment. FIG. 3A is a plan view of the inside surface of a first glass lid 11a (which is a lid 10 of the first piezoelectric device 100). FIG. 3B is a plan view of the crystal frame 20 including a tuning-fork type crystal vibrating piece 21. FIG. 3C is a plan view of a first glass base 31a (which is a base 30 of the first piezoelectric device). FIG. 3D is an elevational cross-section, along the line A-A in FIG. 3B, of the first piezoelectric device 100.

In the first piezoelectric device the first base 31a is attached to the lower surface of the crystal outer frame portion 22 of the crystal frame 20. The first lid 11a is attached to the upper surface of the crystal outer frame portion 22 of the crystal frame 20. Thus, the crystal frame 20 is sandwiched between the first base 31a and the first lid 11a.

The first lid 11a and the first base 31a are made of glass. As FIG. 3A shows, the first lid has a concavity 12 on the surface that faces the crystal outer frame portion in the sandwich.

As FIG. 3B shows, the crystal frame 20 having connecting portions, according to the first embodiment, is used. A respective metal film 45 is formed on both the upper and lower surfaces of crystal outer frame portion 22. The metal film 45 comprises an aluminum (Al) layer having a thickness of about 1000-1500 Ångstroms.

As FIG. 3C shows, the first base 31a has a concavity 32 that faces the crystal outer frame in the sandwich. The first base 31a is made of glass, and the concavity 32 is formed by etching. Concurrently, a first through-hole 33 and second through-hole 34 are formed. A first connecting electrode 46 and second connecting electrode 47 are formed on the depicted surface of the first base 31a.

Inside the first through-hole 33 and second through-hole 34, metal films are formed by a photolithography step at the same time the connecting electrodes 46, 47 are formed. One metal film is gold (Au) and another metal film is silver (Ag). The first base 31a is provided with a first external electrode 48 and a second external electrode 49 that are metalized underneath. The first connecting electrode 46 is connected through the first through-hole 33 to the first external electrode 48 on the lower surface of the first base 31a. Similarly, the second connecting electrode 47 is connected through the second through-hole 34 to the second external electrode 49 on the lower surface of the first base 31a.

The base electrode 41 and second base electrode 42, formed on the lower surface of crystal outer frame portion 22, are connected to the first connecting electrode 46 and second connecting electrode 47, respectively, on the front surface of the first base 31a. Thus, the first base electrode 41 is connected electrically to the first external electrode 48, and the second base electrode 42 is connected electrically to the second external electrode 49.

As FIG. 3D shows, the first lid 11a, the crystal outer frame portion 22, and the first base 31a are placed to form a three-layer sandwich. Then, anodic bonding is performed to complete manufacture of the piezoelectric device. The first lid 11a and first base 31a can be made of, for example, Pyrex® glass, borosilicate glass, or soda glass (all being glasses containing metal ions such as sodium ions). The crystal outer frame portion 22 has respective metal (Al) films 45 on the upper and lower surfaces. The crystal outer frame portion 22 including the tuning-fork type crystal vibrating piece 21 is the center layer in the sandwich, with the first lid 11a having the concavity 12 being the upper sandwich layer, and the first base 31a having the concavity 32 being the lower sandwich layer. Although aluminum (Al) is used as the metal films 45 in this embodiment, any other metal having functionality for anodic bonding can alternatively be used. Also usable are metals that can be anodized, such as titanium (Ti), chromium (Cr), cobalt (Co), nickel (Ni), cadmium (Cd), or tin (Sn).

The vibration frequency of the first piezoelectric device 100 is adjusted during manufacturing. The frequency adjustment is conducted in a vacuum state or in an inert-gas atmosphere in which the first base 31a is bonded to the crystal outer frame portion 22 by anodic bonding. The frequency adjustment will be explained below in the forth embodiment. Then, the first lid 11a is placed on and bonded to the upper surface of the crystal frame 20 by anodic bonding in a vacuum or inert gas atmosphere. Then, the first and second through-holes 33, 34 are sealed using a metallic material, thereby completing manufacture of the piezoelectric device 100.

Anodic bonding is performed by an oxidation reaction of the metal in the bonding interface. For example, during anodic bonding of the crystal outer frame portion 22 to the glass first lid 11a and glass first base 31a, the metal films 45 (formed by sputtering on the upper and lower surfaces of the crystal outer frame portion 22) are bonded to the respective bonding surface of the glass material.

To perform anodic bonding, the metal film is connected as an anode, and a cathode is arranged on a bonding surface of the glass material facing the metal film. An electric potential is applied between the anode and cathode, which causes the metal ions (e.g., sodium) in the glass to migrate to the cathode. This causes oxidation of the metal film at the bonding interfaces, which bonds the materials together. By way of example, in this embodiment, the metal and glass are bonded together by applying a 500 V to 1 kV voltage potential between the anode and cathode at a temperature of 200 to 400° C.

FIG. 3D shows the crystal outer frame portion 22, the first lid 11a, and the first base 31a being bonded together as a unitary single device. In an actual process for manufacturing the devices, hundreds to thousands of crystal frames 20 are formed on a single crystal wafer. A corresponding number and arrangement of first lids 11a are formed on a first glass wafer, and a corresponding number and arrangement of first bases 31a are formed on a second glass wafer. The three wafers are sandwiched and bonded to form hundreds to thousands of piezoelectric devices simultaneously.

### Third Embodiment: Configuration of the Second Piezoelectric Device 110

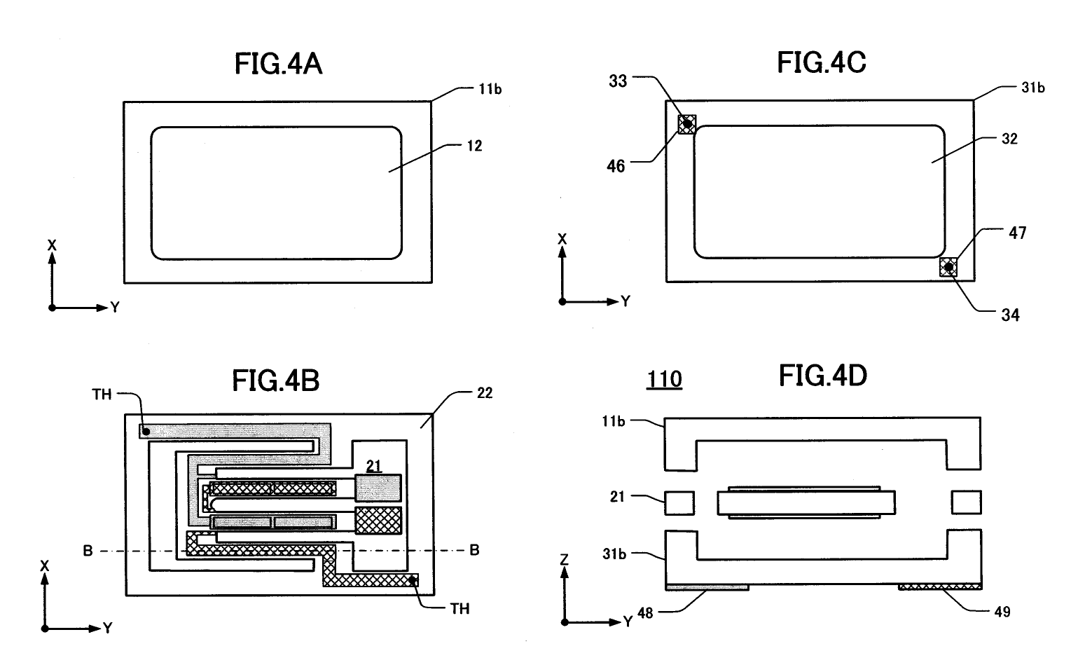

A second piezoelectric device 110, comprising a lid 10, a second layer, and a base 30, is now described with reference to FIGS. 4A-4D. FIGS. 4A-4D are respective schematic orthogonal views of the second piezoelectric device 110 of this embodiment.

FIG. 4A is a plan view of the lower (interior) surface of the second lid 11b formed from a crystal substrate. FIG. 4B is a plan view of the upper surface of the crystal frame 20, and FIG. 4C is a plan view of the upper (interior) surface of the base 31b formed from a crystal substrate. FIG. 4D is an elevational section, along the line B-B in FIG. 4B, of the second piezoelectric device 110.

The second piezoelectric device 110 is formed of three layers of crystal substrates (base, frame, and lid), in which electrodes, through-holes, and other structures are as in the first piezoelectric device 100. Hence, only the differences are described below, in which similar structures have the same reference numbers as used previously.

As FIG. 4B shows, the crystal frame 20 having connecting portions as used in the first embodiment is used. In the embodiment of FIG. 4B the metal film 45 used in the first piezoelectric device 100 is not needed so is not formed. The need for the metal film 45 is obviated because the second lid 11b, the crystal outer frame portion 22, and the second base 31b are bondable by siloxane (Si—O—Si) bonding.

The vibration frequency of the second piezoelectric device 100 is also adjusted during manufacture. The frequency adjustment is performed in a vacuum or inert-gas environment. First, the second base 31b and crystal outer frame portion 22 are bonded together by siloxane bonding. Then, the vibration frequency is adjusted (as described in the forth embodiment). Then, the second lid 11b is bonded by siloxane bonding in the vacuum or inert-gas environment. Then, the first and second through-holes 33, 34 are filled with a metallic material, thereby completing manufacture of the second piezoelectric device 110.

The bonding surfaces for siloxane bonding must have a mirror finish to avoid electrode thicknesses of 3000 to 40,000 Ångstroms causing imperfect contacts. Hence, the surface (the lower surface of the crystal outer frame portion 22) facing the first and second base electrodes 41, 42 desirably has a concavity of sufficient depth to accommodate the thickness of the wiring electrodes. Similarly, the surface (the upper surface of the second base 31b) facing the first and second connecting electrodes 46, 47 desirably has a concavity of sufficient depth to accommodate the thickness of the connecting electrodes. Bonding surfaces, formed in this manner with concavities facing respective electrodes, do not inhibit siloxane bonding.

FIG. 4D shows the crystal outer frame portion 21, the second lid 11b, and the second base 31b being bonded together as a unitary single device. In an actual process for manufacturing the devices, hundreds to thousands of crystal frames 20 are formed on a first crystal wafer. A corresponding number and arrangement of second lids 11b are formed on a second crystal wafer, and a corresponding number and arrangement of second bases 31b are formed on a third crystal wafer. The three wafers are sandwiched and bonded to form hundreds to thousands of piezoelectric devices simultaneously.

### Fourth Embodiment: Frequency-Adjustment Method

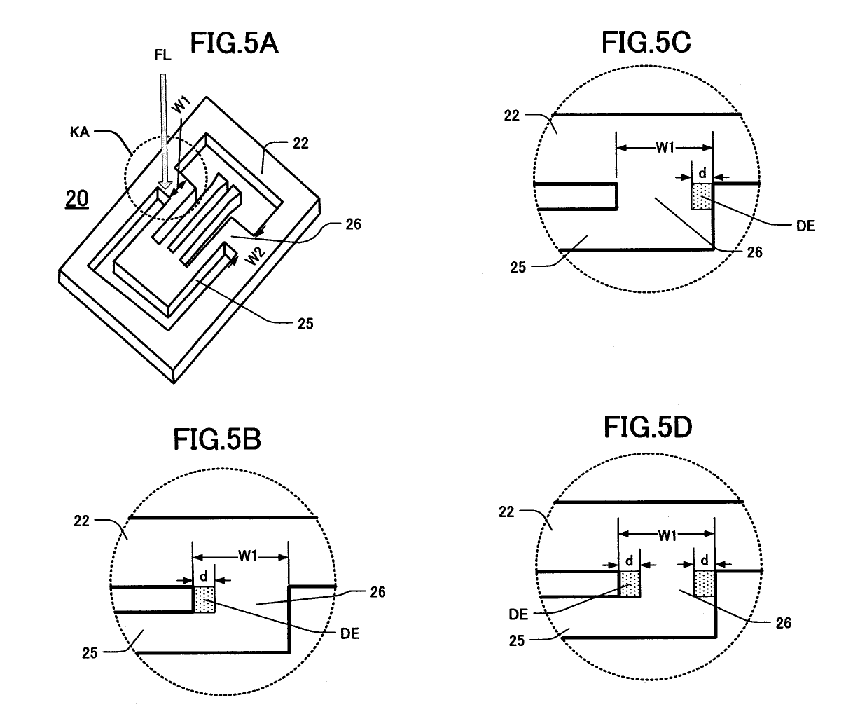

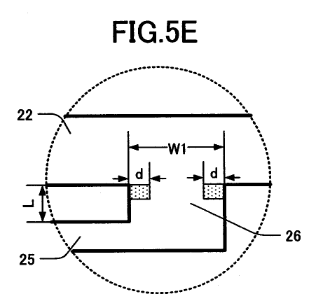

As described in the second and third embodiments, frequency adjustment is conducted during manufacture of the piezoelectric devices, FIG. 5A shows frequency adjustment being conducted on the crystal frame 20 having connecting portions using, for example, a femtosecond-pulsed laser FL. Vibration frequency is changed by cutting away a portion of the connecting portion 26 in the Y-direction. Cutting is conducted on both connecting portions 26, shown as having respective widths W1 and W2. Both widths W1, W2 are the same. FIGS. 5A-5D show enlargements of detail within the area of the dashed-line circle KA of FIG. 5A.

FIG. 5B shows frequency adjustment being performed by cutting away a part DE of the connecting portion 26 closer to the base portion. FIG. 5C shows frequency adjustment being performed by cutting away a part DE of the connecting portion closer to the tip of vibrating arm. FIG. 5C is an alternative procedure to that shown in FIG. 5B. FIG. 5D shows frequency adjustment being performed by cutting away both parts DE. FIG. 5D is an alternative procedure to either of FIGS. 5B or 5C. Both widths W1 and W2 of the connecting portions are similarly cut to a width d according to any of FIGS. 5B to 5D using a femtosecond laser FL or other suitable cutting technique.

FIG. 5E shows an alternative cutting pattern of the part DE of the connecting portion 26 when, for example, the width L is greater than shown in FIG. 5C. The parts DE in FIG. 5E are not cut with the same length as length L; rather, they are cut with a length only half the length L, compared to FIG. 5D. In FIG. 5E, by narrowing the part DE to be cut, the amount actually cut by the laser is reduced. The effect is a shortened adjustment time for the same degree of frequency change.

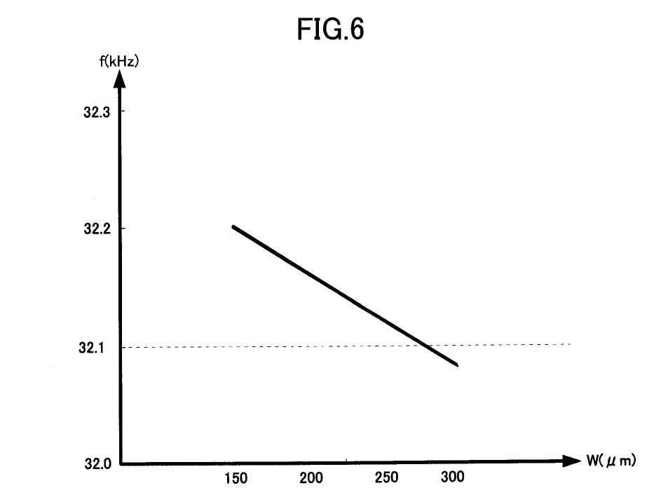

FIG. 6 is a graph of experimental data, showing the relationship between the width W of the connecting portion on both sides of the tuning fork and the frequency f. The experiment shows that the frequency is increased about 3600 ppm when the width W is changed from 300 μm to 150 μm. Thus, by first fabricating the piezoelectric device to have a lower vibration frequency and making the width W narrower, the frequency can be adjusted finely to 32.768 kHz, for example. As stated above, this frequency-adjustment method is not conducted during fabricating the vibrating arms 24 of the tuning-fork type crystal vibrating piece 21; consequently, the frequency adjustment can be conducted without changing the characteristics of the tuning-fork type crystal vibrating piece 21.

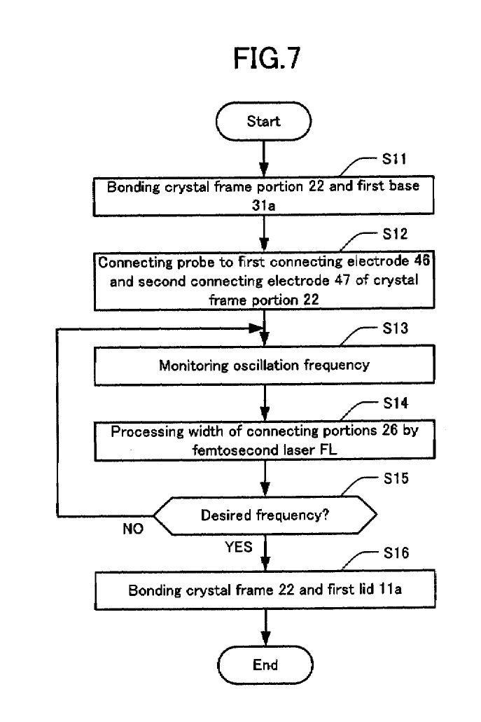

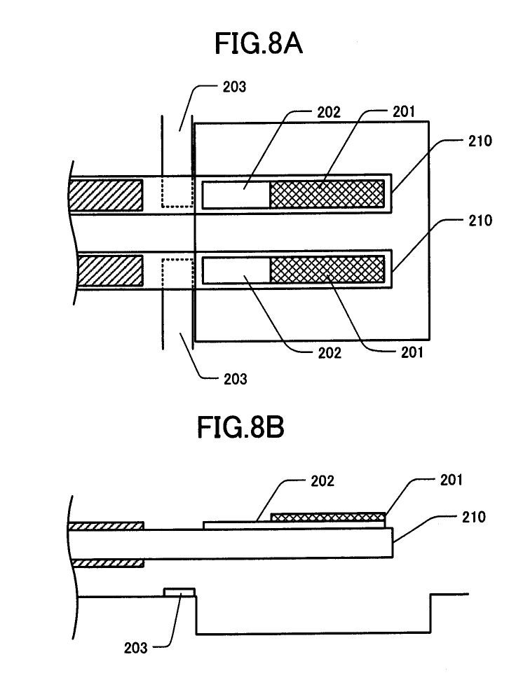

FIG. 7 is a flow-chart of an embodiment of a frequency-adjustment process. Whereas only the frequency adjustment of the first piezoelectric device 100 is described below, it will be understood that the vibration frequency of the second piezoelectric device 110 can be adjusted in a similar manner.

In step S11 the crystal outer frame portion 22 and the first base 31a are bonded together by anodic bonding and arranged for frequency adjustment. In step S12 a probe (not shown) is placed in contact with the first base electrode 41 and the second base electrode 42 of the crystal frame portion 22 to cause vibration of the tuning-fork type crystal vibrating piece 21 for oscillation-frequency measurement. The probe is needle-like and the needle directly contacts the delicate electrode. Since the electrode is easily damaged, the probe needle desirably is connected to locations on the electrode where electrically conduction by the electrode would not be damaged if the needle should scratch the surface of the electrode. Preferable locations on the base electrodes 41, 42 for probe contact are the end portions on the upper surface of the crystal frame 20.

In step S13, the vibration frequency of the tuning-fork type crystal vibrating piece 21 is monitored using a frequency-measuring device (not shown). In step S14 a femtosecond laser FL is used to make a desired cut width d for producing a designated oscillation frequency, while the width W of both connecting portions are made narrow.

In step S15 the frequency-measurement device evaluates whether the frequency is a desired value. If not at the desired frequency, the process returns to step S13 so that the width W of each connecting portion is cut narrower. On the other hand, if the frequency is as desired, then frequency adjustment is completed and the process advances to step S16. In step S16, since the frequency adjustment of the tuning-fork type crystal vibrating piece 21 is completed, the process advances (in step S16) to an anodic bonding step. In this step, the crystal outer frame portion 22 (with the tuning-fork type crystal vibrating piece 21) and the first lid 11a are bonded together by anodic bonding in a vacuum or inert gas atmosphere.

The frequency adjustment can be conducted in a situation in which the first base 31a has already been bonded by anodic bonding so that the vibration frequency remains substantially unchanged after the first lid 11a is bonded. Although the flow-chart of FIG. 7 shows the crystal outer frame portion 22 and the first base 31a being bonded together by anodic bonding first, in an alternative embodiment the first lid 11a and the first base 31a are bonded together by anodic bonding after the vibration frequency of the crystal outer frame portion has been adjusted.

Representative embodiments are described above. It will be understood that these embodiments can be modified or changed while not departing from the spirit and scope of them and/or of the appended claims.

In an exemplary modification, lithium niobate or piezoelectric material other than quartz crystal can be used for the crystal frame 20 having tuning-fork type crystal vibrating piece 21.

What is claimed is:

1. A piezoelectric frame, comprising:
a tuning-fork type piezoelectric vibrating piece comprising a base portion, at least a pair of vibrating arms extending in a first direction from one edge of the base portion, and respective excitation electrodes on the vibrating arms;
a respective supporting arm extending in the first direction from an external edge of each vibrating arm;
an outer frame portion surrounding the tuning-fork type piezoelectric vibrating piece; and
respective connecting portions having designated widths connecting the supporting arms to the outer frame portion.

2. The piezoelectric frame of claim 1, wherein the connecting portions are cut to have their designated widths adjustably narrowed so that the tuning-fork type piezoelectric vibrating piece oscillates with a designated frequency.

3. The piezoelectric frame of claim 2, wherein the connecting electrodes are formed on the outer frame portion and are electrically connected to respective excitation electrodes.

4. The piezoelectric frame of claim 1, wherein the connecting electrodes are formed on the outer frame portion and are electrically connected to respective excitation electrodes.

5. A piezoelectric device, comprising:
a piezoelectric frame as recited in claim 1;
a lid covering the piezoelectric frame; and
a base supporting the piezoelectric frame.

6. The piezoelectric device of claim 5, wherein:
the lid and base are each made of a glass including metal ions;
a respective metal film is situated on each of the upper and lower surfaces of the outer frame portion of the piezoelectric frame; and
the lid and base are bonded to the piezoelectric frame by anodic bonding involving the metal films.

7. The piezoelectric device of claim 5, wherein:
the lid and the base are each made of a piezoelectric material; and
the piezoelectric frame, the lid, and the base are bonded together by siloxane bonding.

8. A method for adjusting vibration frequency of a piezoelectric device, comprising:
forming a piezoelectric frame having a tuning-fork type piezoelectric vibrating piece comprising (a) at least two vibrating arms extending in a first direction from one edge of a base portion, (b) respective excitation electrodes on each vibrating arms, (c) a respective supporting arm for each vibrating arm, the supporting arms extending in an extension direction of the vibrating arms from respective outer edges of the vibrating arms, (d) an outer frame portion surrounding the tuning-fork type piezoelectric vibrating piece, and (e) a respective connecting portion having a designated width connecting each supporting arm to the outer frame portion;
measuring oscillation frequency of the vibrating arms by connecting a potential to the excitation electrodes; and
trimming material from the designated width of the connecting portion, based on the measured oscillation frequency, so as to remove mass from the connecting portion and correspondingly increase the vibration frequency.

9. The method of claim 8, wherein:
the outer frame portion includes connecting electrodes electrically connected to the excitation electrodes; and
the measuring step comprises contacting a probe to the connecting electrodes to measure oscillation frequency.

10. The method of claim 9, further comprising a first bonding step, in which a base supporting the piezoelectric frame and the piezoelectric frame are bonded together, wherein measuring and trimming are performed after the first bonding step.

11. The method of claim 10, further comprising a second bonding step, in which a lid covering the piezoelectric frame is bonded to the piezoelectric frame in a vacuum environment after the trimming step.

12. The method of claim 8, further comprising a first bonding step, in which a base supporting the piezoelectric frame and the piezoelectric frame are bonded together, wherein measuring and trimming are performed after the first bonding step.

13. The method of claim 12, further comprising a second bonding step, in which a lid covering the piezoelectric frame is bonded to the piezoelectric frame in a vacuum environment after the trimming step.

14. The method of claim 8, wherein the trimming step is performed using a pulsed laser.
